(19) United States
(12) Patent Application Publication
(10) Pub. No.: US 2024/0341249 A1
(43) Pub. Date: Oct. 17, 2024

(54) MODELING OF SOIL COMPACTION AND STRUCTURAL CAPACITY FOR FIELD TRAFFICABILITY BY AGRICULTURAL EQUIPMENT FROM DIAGNOSIS AND PREDICTION OF SOIL AND WEATHER CONDITIONS ASSOCIATED WITH USER-PROVIDED FEEDBACK

(71) Applicant: DTN, LLC, OMAHA, NE (US)

(72) Inventors: JOHN J. MEWES, MAYVILLE, ND (US); DUSTIN M. SALENTINY, GRAND FORKS, ND (US)

(21) Appl. No.: 18/545,371

(22) Filed: Dec. 19, 2023

Related U.S. Application Data
(63) Continuation of application No. 18/094,203, filed on Jan. 6, 2023.
Application No. 18/094,203 is a continuation-in-part of application No. 15/049,044, filed on Feb. 20, 2016, now abandoned.
Application No. 18/094,203 is a continuation-in-part of application No. 17/340,774, filed on Jun. 7, 2021, now Pat. No. 11,672,212.
Application No. 17/340,774 is a continuation of application No. 16/179,559, filed on Nov. 2, 2018, now Pat. No. 11,026,376.
Application No. 16/179,559 is a continuation-in-part of application No. 15/883,017, filed on Jan. 29, 2018, now Pat. No. 10,139,797.
Application No. 15/883,017 is a continuation of application No. 15/229,968, filed on Aug. 5, 2016, now Pat. No. 9,880,537.
Application No. 18/094,203 is a continuation-in-part of application No. 16/101,302, filed on Aug. 10, 2018, now abandoned.
(60) Provisional application No. 62/118,615, filed on Feb. 20, 2015.
(60) Provisional application No. 62/201,117, filed on Aug. 5, 2015.
(60) Provisional application No. 62/543,638, filed on Aug. 10, 2017.

(51) Int. Cl. A01G 25/16; A01B 79/00; A01G 25/02; G01W 1/10; G06F 30/20

(52) U.S. Cl. CPC A01G 25/167; A01B 79/005; A01G 25/023; G01W 1/10; G06F 30/20

(57) ABSTRACT

A multi-step iterative process for simulating complex agricultural situations where limited sets of data are available for such problems first predicts an outcome for each situation in a particular dataset, using initial assumptions of an applied primary model. The process then uses the errors across these situations to identify where opportunities exist among relevant predictive variables for the model to make changes to a response to such predictor variables to reduce the errors when averaged across all situations. The process then develops a correction model to identify adjustments based on combinations of the predictive variables, and applies the adjustments to the primary model to induce an altered outcome.

### CROSS-REFERENCE TO RELATED APPLICATIONS

This application is a continuation application of U.S. patent application Ser. No. 18/094,203, filed Jan. 6, 2023, which is a continuation-in-part of:
U.S. patent application Ser. No. 15/049,044, filed Feb. 20, 2016, which claims priority pursuant to 35 U.S.C. 119 (e) to U.S. Provisional Patent Application Ser. No. 62/118,615, filed Feb. 20, 2015, the entire disclosures of which are incorporated herein by reference;
U.S. patent application Ser. No. 17/340,774, filed Jun. 7, 2021, which is a continuation of U.S. application Ser. No. 16/179,559, filed Nov. 2, 2018, now U.S. Pat. No. 11,026,376, which is a continuation in part of U.S. patent application Ser. No. 15/883,017, filed Jan. 29, 2018, now U.S. Pat. No. 10,139,797, which is a continuation of U.S. patent application Ser. No. 15/229,968, filed Aug. 5, 2016, now U.S. Pat. No. 9,880,537, which claims priority pursuant to 35 U.S.C. 119 (e) to U.S. Provisional Patent Application Ser. No. 62/201,117, filed Aug. 5, 2015, the entire disclosures of which are incorporated herein by reference; and
U.S. patent application Ser. No. 16/101,302, filed Aug. 10, 2018, which claims priority pursuant to 35 U.S.C. 119 (e) to U.S. Provisional Patent Application Ser. No. 62/543,638, filed Aug. 10, 2017, the entire disclosure of which is incorporated herein by reference.

### FIELD OF THE INVENTION

The present invention relates to precision agriculture. Specifically, the present invention relates to a technique for generating complex simulation models, including artificial intelligence (AI) models, for analyzing a wide range of agricultural problems, where limited sets of data are available.

### BACKGROUND

A major obstacle to the successful application of ‘big data’ modeling to agricultural problems has been that data related to the agricultural processes to be simulated are often only recorded at a small number of times (and very often, just once) during any one specific case of the process, while that process actually occurs over potentially substantial periods of time, and often in response to changing plant physiological factors such as diseases, nutrient, and chemical applications, changing environmental factors such as soil, weather, and other environmental conditions, and changing ecosystem factors such as pests, canopy competition, and root competition. Both internal and external factors are collectively called “environmental” factors. For instance, a particular dataset for use in developing a crop growth model may contain information on the plant date and the date of a key growth stage for a particular crop across a range of locations and seasons, whereas one may wish to construct a model to simulate the growth of the crop on a daily basis for the entirety of the period between planting and that key growth stage. The complicating factor in doing so is that there are any number of ways in which the crop could have grown on the intervening days in order to arrive at that key growth stage on the observed date. This problem has restricted the agricultural industry's ability to realize the full benefit of some types of large-scale collections of data.

The use of artificial intelligence in analyzing data is now prevalent, and one of the most common artificial intelligence-based tools for identifying and learning patterns in such large-scale data collections, often referred to as “big data,” is the artificial neural network (ANN). In particular, neural networks trained through a technique referred to as backpropagation are able to learn the associations between a set of predictive variables (the ‘predictors’), and a measured response or outcome (the ‘target’). Neural networks may also be trained by any number of other optimization techniques (such techniques include, for example, the stochastic gradient descent, particle swarm optimization, and genetic algorithm methods). Once trained, the ANN can then be used to predict responses or outcomes in new situations, where only the values of the predictors are known, or, in some cases, where additional predictors can themselves be generated from known predictors and used to aid in the prediction of responses or outcomes in new situations. For example, if crop yields are measured across a range of situations, ANNs can be used to identify how these observed yields related to underlying environmental conditions (phosphorous applied, fungicide applied, relative maturity rating, soil type, growing degree days, and total precipitation, using a simple example). Then, going forward, the ANN trained on historical yield and environmental data can be applied to new environmental data (such as for a new growing season and/or new location) in order to predict the yield of a crop that has yet to be harvested.

In the plant date/key growth stage example from above, a dataset may indicate the planting or transplanting date of a crop in a particular location and season, as well as the date on which the crop reached maturity. One can develop an ANN, trained using observed environmental conditions, in order to predict the date of crop maturity in a new location and/or season. However, what if one also wishes to be able to predict the rate of progress toward crop maturity on any given date, or predict the dates on which the same crop reached (or will reach) other key growth stages? For the latter, one could certainly apply established relationships concerning the timing of other growth stages relative to that key growth stage, garnered from the existing body of community knowledge about the crop (though the extent of the scientific community's understanding of these relationships is often quite limited). However, since there are any number of ways in which the crop could have evolved over time in order to arrive in the same given key growth stage on the same given date, those other growth stages cannot be predicted in this manner with the same level of accuracy as the one for which there are direct measurements to train the ANN with. In this example, the methodology of the present invention represents a solution to these problems in the form of a multi-step approach that permits reconstruction of the likely evolution of the crop between the date of planting/transplanting and the date of maturity.

### SUMMARY

The aforementioned problems in the existing art of dealing with large-scale datasets can be addressed by applying a multi-step iterative modeling process that initially predicts an outcome for each situation in a particular dataset using current assumptions of a model, and then uses errors across these situations to identify where opportunities exist in the predictor space to make changes to the model's response to those predictor values that would reduce the model's error when averaged across all situations. While there are any number of ways in which the technique can be applied, it is most easily explained using the specific examples discussed further herein.

While ANNs are a powerful tool for learning the important relationships that may be present in collections of big data, it should be noted that the methodology set forth in the present invention is also applicable to the broader range of approaches that can be used to identify relationships in (and create models from) big data. Accordingly, it is to be understood that ANNs are but one approach to learning such relationships, and many other techniques can be applied in this multi-step iterative modeling process to achieve the objectives set forth herein.

It is therefore one objective of the present invention to provide a system and method of developing simulation models for agricultural problems where available data provide only a limited picture of the problem at hand, and where the simulated state of the system at any given point in time is dependent upon the states of the system at preceding times. It is another objective of the present invention to develop simulation models for such agricultural problems by inferring associations between a set of predictive variables in input data relative to the agricultural problem and a measured response or outcome of a simulation, and applying the predictive variables to predict responses or outcomes in new situations.

Other objects, embodiments, features, and advantages of the present invention will become apparent from the following description of the embodiments, taken together with the accompanying drawings, which illustrate, by way of example, the principles of the invention.

### BRIEF DESCRIPTION

The accompanying drawings, which are incorporated in and constitute a part of this specification, illustrate several embodiments of the invention and together with the description, serve to explain the principles of the invention.

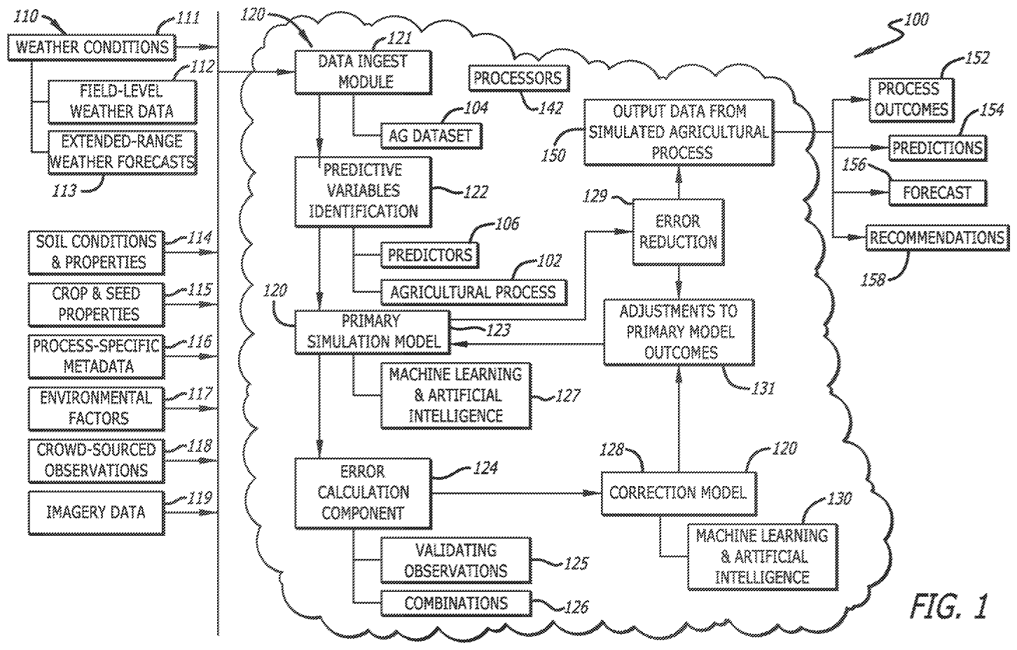

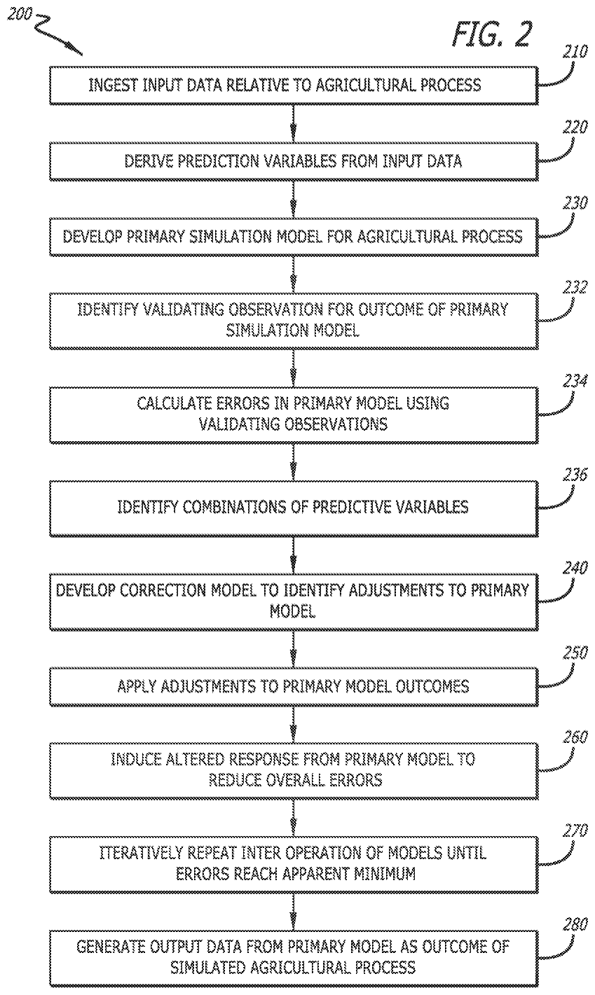

FIG. 1 is a block diagram illustrating system components in a multi-step iterative modeling process according to one embodiment of the present invention.

FIG. 2 is a flowchart of steps in a multi-step iterative modeling process according to one embodiment of the present invention.

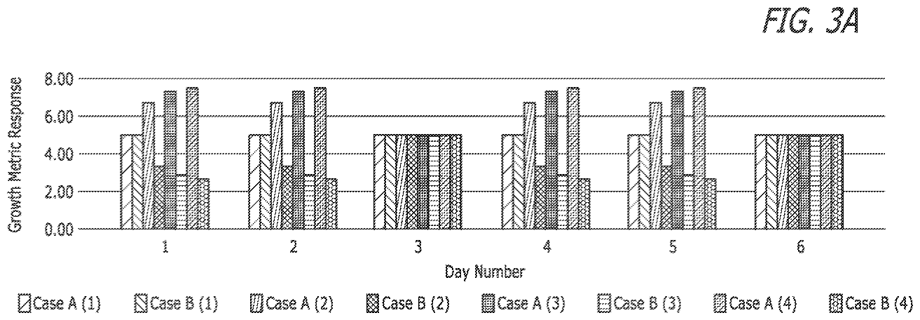

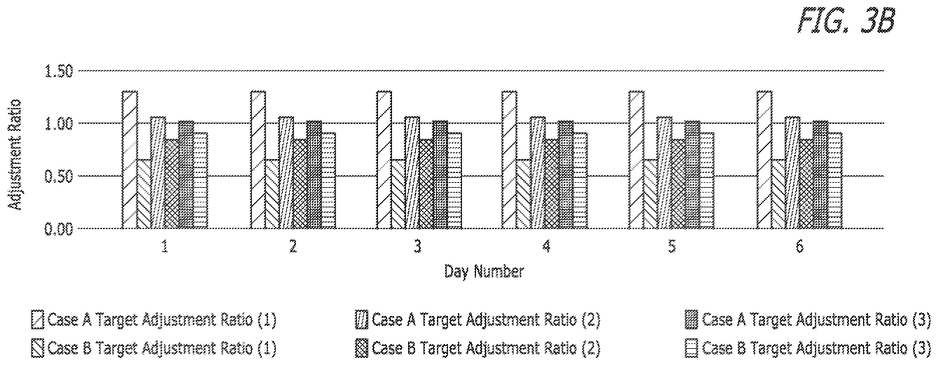

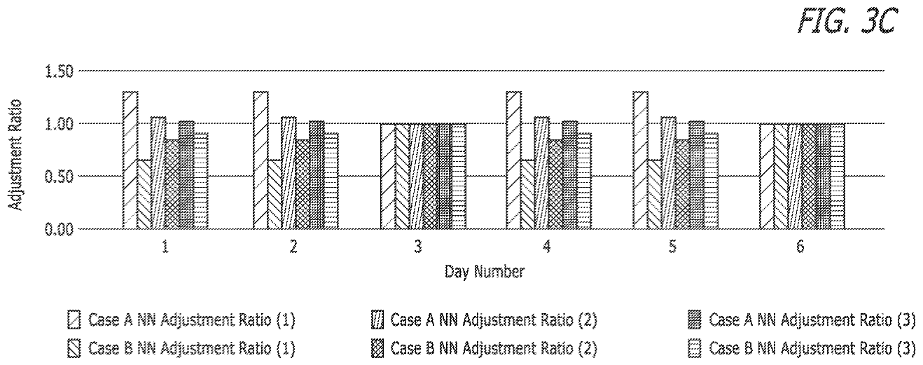

FIG. 3A is an exemplary illustration of a growth metric response in simulation outcomes of agricultural processes according to the present invention.

FIG. 3B is an exemplary illustration of a ‘targeted’ adjustment ratio for simulating agricultural processes according to the present invention.

FIG. 3C is an exemplary illustration of a ‘trained’ adjustment ratio for simulating agricultural processes according to the present invention.

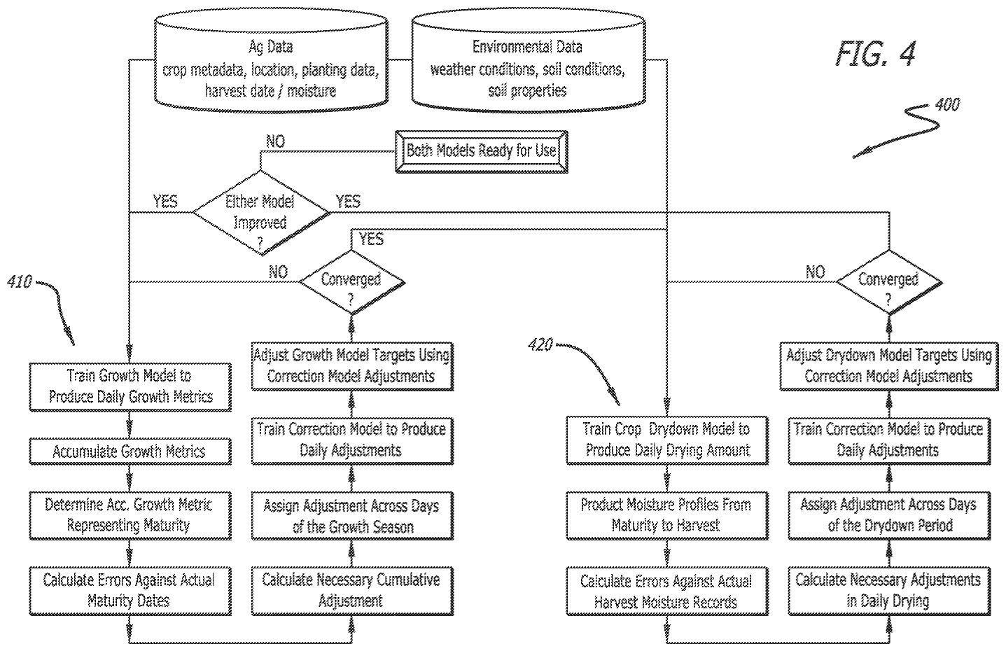

FIG. 4 is a flow diagram illustrating a process of automatically developing separate models of interdependent problems from a common dataset according to the present invention.

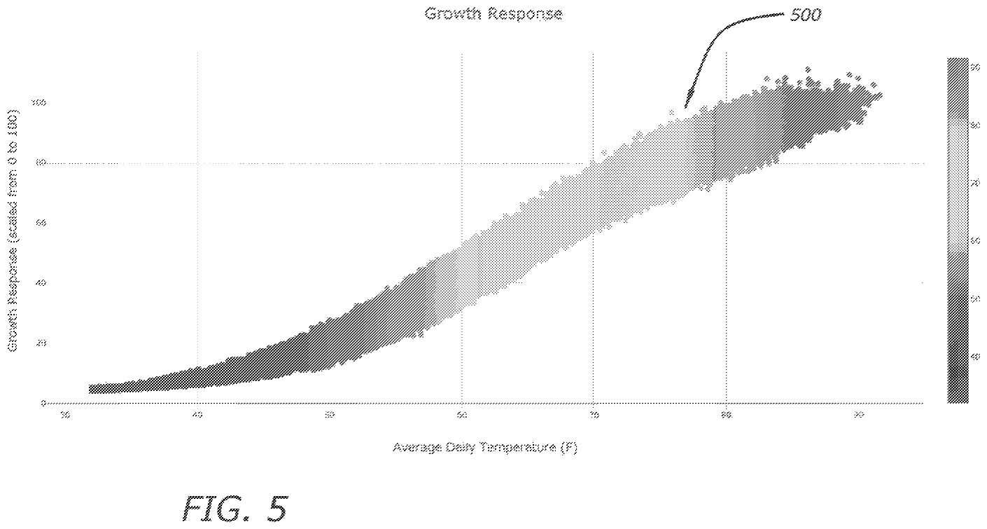

FIG. 5 is a plot of data points illustrating a growth response function according to the present invention.

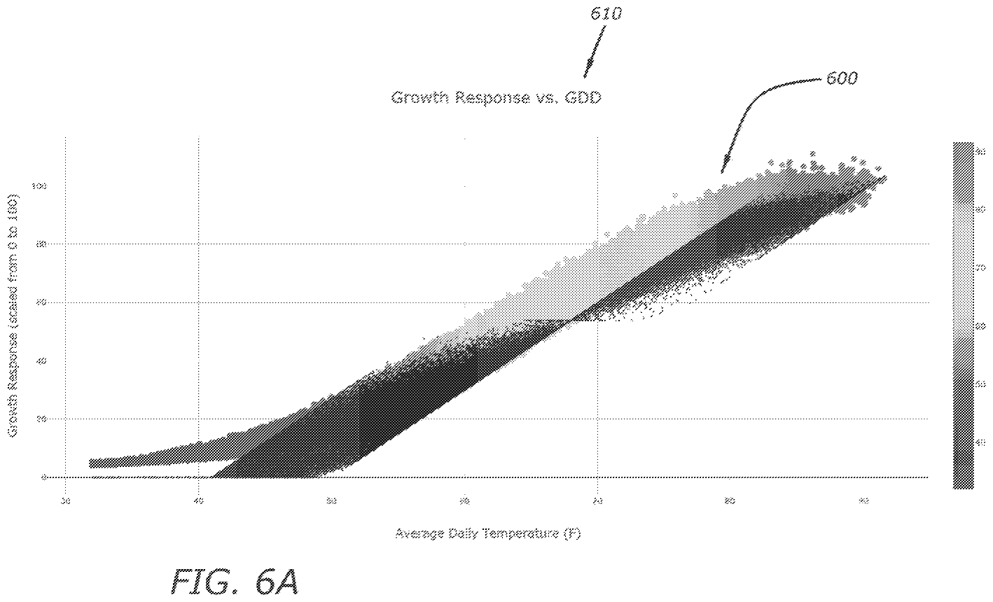

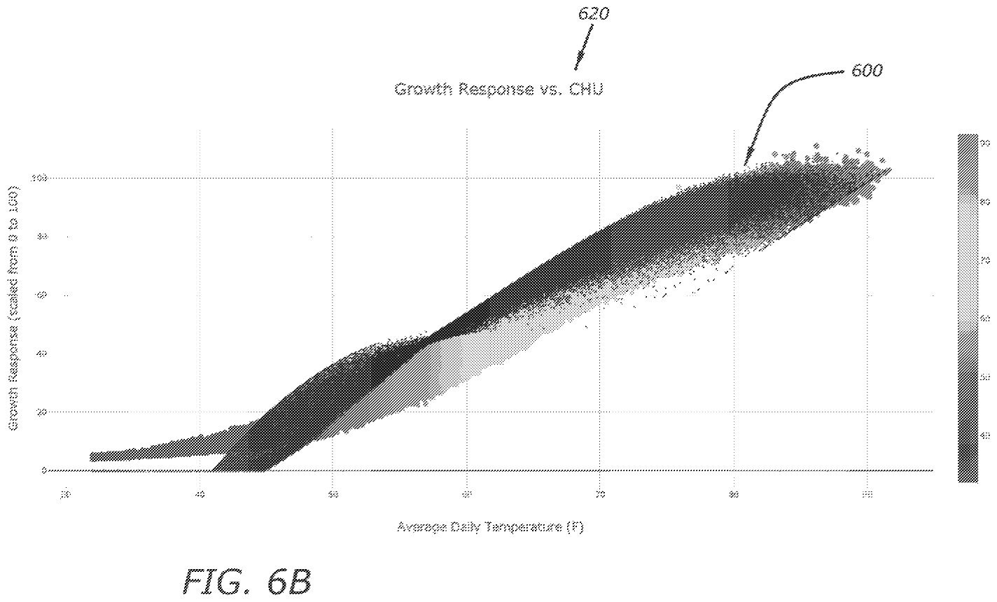

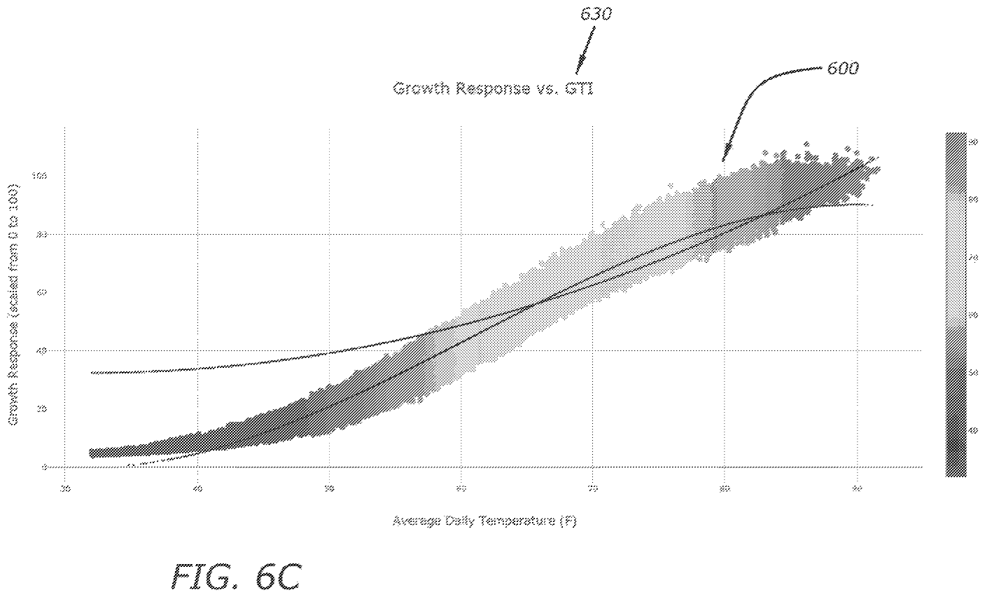

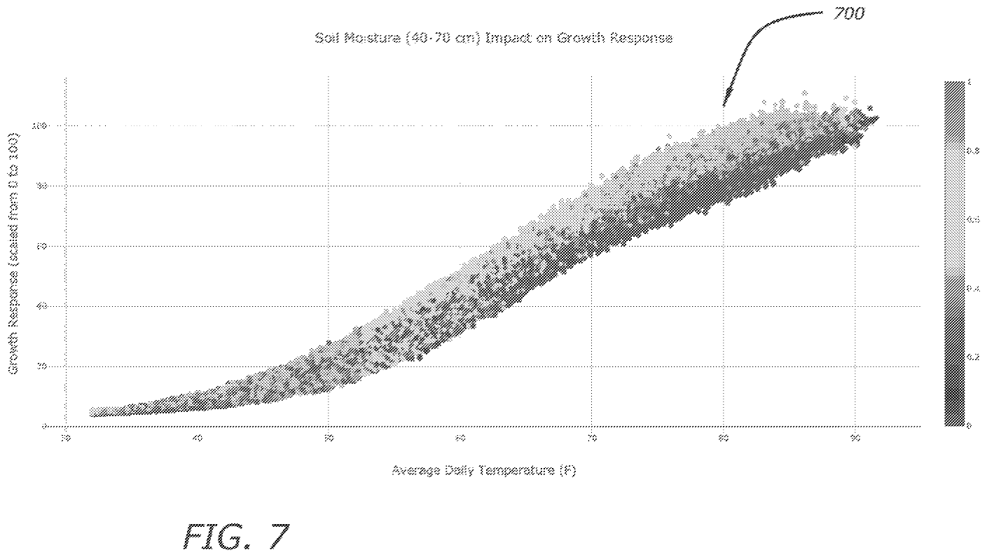

FIG. 6A is a plot of data points illustrating a daily growth response function as determined from growing degree days (GDD).

FIG. 6B is a plot of data points illustrating a daily growth response function as determined from crop heat units (CHU).

FIG. 6C is a plot of data points illustrating a daily growth response function as determined from a general thermal index (GTI).

FIG. 7 is a plot of data points illustrating an impact of soil moisture on the daily growth response according to one implementation of the present invention.

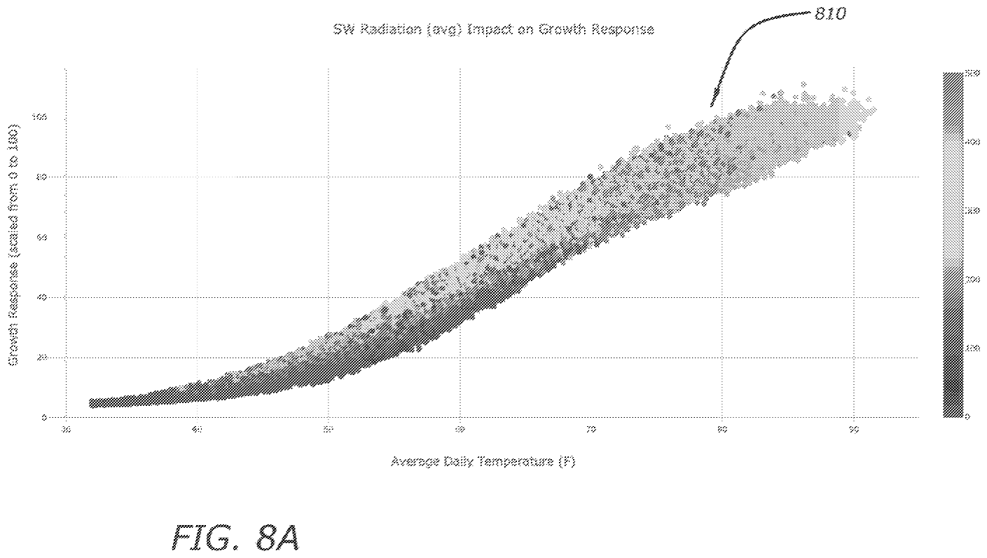

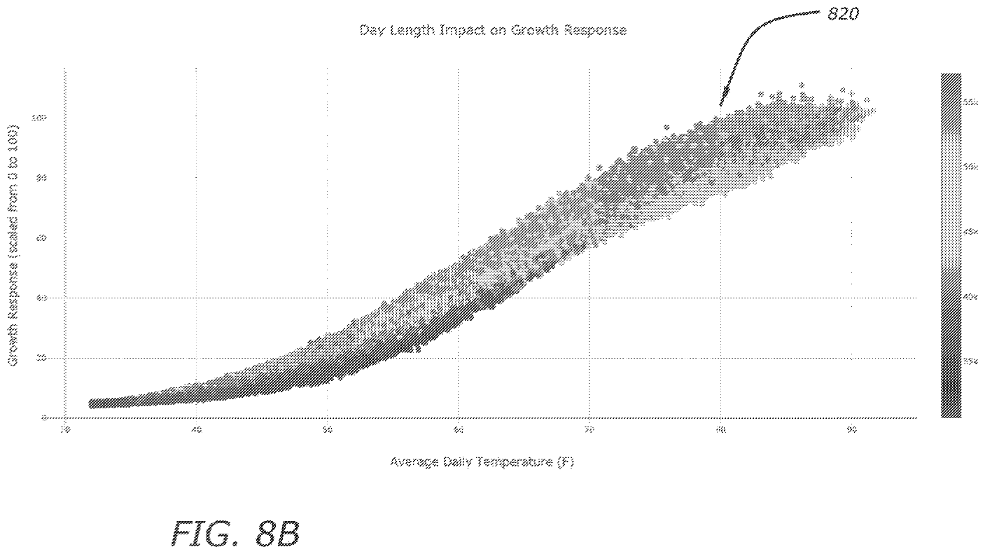

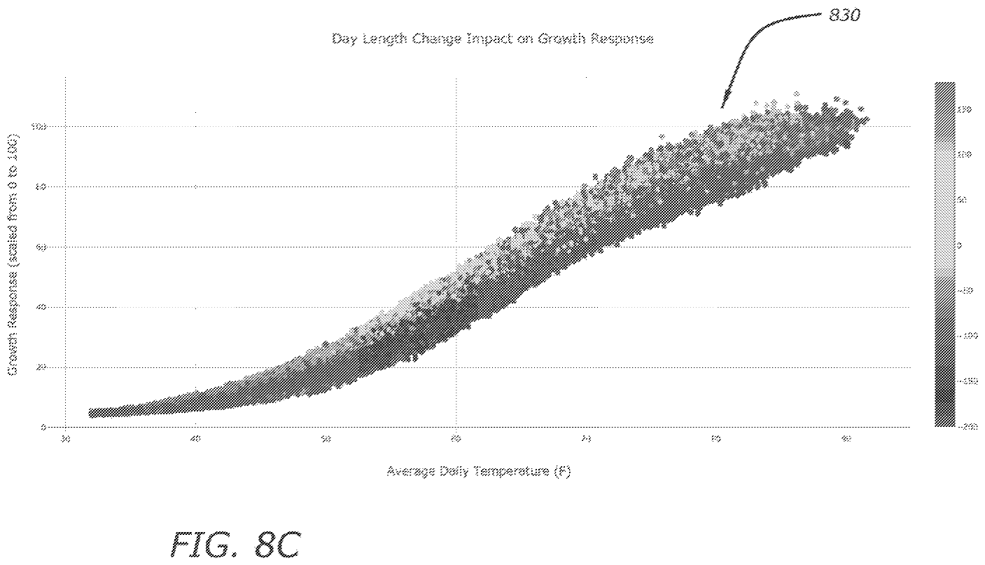

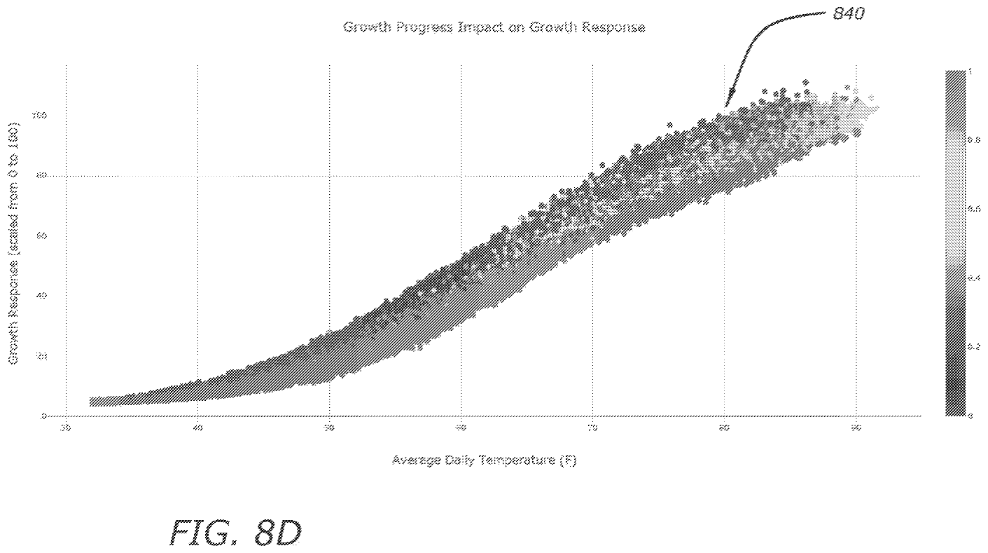

FIG. 8A is a plot of data points illustrating the impact of average daily solar radiation on the daily growth response according to one implementation of the present invention.

FIG. 8B is a plot of data points illustrating the impact of day length on the daily growth response according to one implementation of the present invention.

FIG. 8C is a plot of data points illustrating the impact of day length change on the daily growth response according to one implementation of the present invention.

FIG. 8D is a plot of data points illustrating the impact of growth progress on the daily growth response according to one implementation of the present invention.

### DETAILED DESCRIPTION

In the following description of the present invention, reference is made to the exemplary embodiments illustrating the principles of the present invention and how it is practiced. Other embodiments will be utilized to practice the present invention, and structural and functional changes will be made thereto without departing from the scope of the present invention.

As noted above, the present invention is a multi-step iterative modeling process 100 for addressing limitations in the use of large-scale datasets for modeling complex agricultural processes 102. Such an iterative modeling process 100 first predicts an outcome for each situation in a particular dataset 104 using the present assumptions of the model, and then uses errors measured across the range of such situations to identify where opportunities exist in the predictor space to make changes to the model's response to combinations of the individual predictors' values in such a way as to reduce the model's error when averaged across all situations.

FIG. 1 is a block diagram of system components in the multi-step iterative modeling process 100 of the present invention, which is performed in one or more systems and methods in which input data 110 are processed to define a set of predictive variables, or input predictors, 106. These predictors 106 are used to develop a primary model for simulating complex agricultural processes 102. Errors in the primary model are then calculated using validating observations from data points related to the agricultural process. The process 100 then develops a ‘correction model’ which identifies opportunities for making adjustments to the output of the primary model for a given combination of input predictors in such a way that the average errors of the primary model across all situations is reduced. This correction model is then used to induce an altered response from the primary model, for each combination of input predictor values, such that overall errors will be reduced. The outcome of this multi-step approach improves the use of large-scale datasets in agricultural modeling, to support enhanced agronomic decision-making in precision agriculture.

In this multi-step iterative modeling process 100, input data 110 that defines variables 106 relevant to an agricultural process 102, including one or more of weather conditions 111 (including field-level weather data 112 and extended-range weather forecasts 113, as discussed further herein), soil conditions and properties 114, crop and seed properties 115, process-specific metadata 116 over a period of time, and other environmental factors 117, is predicted, ingested, received, requested, or otherwise obtained as described herein. These predictors, as noted above, are a set of environmental and process-specific variables 106 that are selected because they are expected to have some predictive influence on the agricultural process 102 to be modeled. Depending on the specific agricultural processes 102 being modeled, the variables/predictors 106 are selected at least in part by a degree of association between input data 110 and a desired response or outcome of the process being simulated. Input data 110 may therefore include many different types of information, as discussed further herein, depending upon the agricultural process 102 to be modeled.

Input data 110 may be obtained from a number of different sources of such information. For example, input data 110 may be proprietary or may be obtained from third party sources. Input data 110 may also represent the outcomes of other modeling approaches, proprietary or otherwise, for one or more of the types of input data 110 used to define predictors 106 for developing the models discussed herein. Input data 110 may also be obtained from other external sources such as agricultural equipment, from crowd-sourced observations 118 such as from mobile applications or from users directly. Input data 110 may also include image data 119, for example information extracted from imagery of a field, and imagery may include one or more images that are obtained from a variety of different sources, for example satellites, field-based robots, aircraft, and remotely-piloted or unmanned vehicles.

Process-specific metadata 116 may include information reflecting actual performance, realization, or implementation of one or more of crops, plants, fields, soils, and facilities in a desired agricultural process to be modeled. This metadata 116 may include, for example, crop and seed metadata that including relative maturity rating, dry-down characteristics of the variety of crop or seed used in a particular field, pest and disease susceptibility or resistance, whether a crop is irrigated or non-irrigated, type and origin of seeds (such as, for example, genetically modified or non-genetically modified, and company source), soil texture composition, amounts of additional applied minerals (e.g., nitrogen, potassium), and amounts and timing of any fungicides, herbicides, pesticides, plant growth regulators, and desiccants. Such metadata may also include soils metadata such as information relating to previous crop grown on or in the soil, soil composition, presence of surface and/or subsurface drainage, nutrient composition, rate of degradation, rate of water movement in both a lateral and vertical direction, presence of materials such as salts in soil strata, and farming practices such as the type(s) of tillage performed in the field, and when.

The input data 110 may also include crop and seed properties 115, representing crop and planting information for a crop-related agricultural process 102. This may include generalized crop and seed data, such as crop type, seed type, planting data, growing season data; relative maturity, planting or emergence date, crop temperature, crop moisture, seed moisture, plant depth, row width, and any other non process-specific crop and plant information that may be used to model a desired agricultural process 102. Crop properties 115 may further comprise crop management information that incorporates all of the above types of data. Regardless, crop and planting information may be provided as output data from one or more additional, external models that serve as sources of further input data 110 at least related to crops and seeds for the multi-step iterative modeling process 100 of the present invention.

Regardless, the multi-step iterative modeling process 100 is performed at least in part by applying this input data 110 to a plurality of data processing components 120 within a computing environment 140 that also includes one or more processors 142, a plurality of software and hardware components, and one or more modular software and hardware packages configured to perform specific processing functions. The one or more processors 142, plurality of software and hardware components, and one or more modular software and hardware packages are configured to execute program instructions to perform algorithms for various functions within the multi-step iterative modeling process 100 that are described in detail herein, and embodied in one or more modules comprising the plurality of data processing components 120.

The plurality of data processing components 120 include a data ingest component 121 configured to ingest, receive, request, or otherwise obtain the input data 110 as noted above. This may include a component 122 for processing predictors 106 that are developed by identifying variables relevant to an agricultural process 102 to be simulated. Such development may occur externally, as noted below, based on expert knowledge of the agricultural process being modeled, the findings of previous research related to the problem at hand, through statistical analysis of aggregate metrics of environmental conditions over the locations and periods of the data points in the observed dataset 106, or simply through trial and error.

The data processing components 120 also include a component configured to develop the primary simulation model 123 within the multi-step iterative modeling process 100. The plurality of data processing modules 120 also include an error calculation component 124, configured to calculate errors in an outcome of the primary simulation model 123 at least by identifying one or more validating observations 125 in such an outcome, and by identifying combinations among the predictive variables influencing these observations 125. The primary simulation model 123 may also include one or more layers of machine learning and artificial intelligence models 127, trained to identify relationships among the variables and predictors 106 and associated combinations 126 thereof for at least the error calculation aspect of the primary simulation model 123.

The plurality of data processing components 120 also include a component configured to develop a correction model 128, which is at least configured to reduce errors 129 in the primary simulation model 123 until such errors 129 reach an apparent minimum (or other error reduction target) that may depend, for example, on the type of agricultural process 102 being modeled. The correction model 128 may also include one or more layers of machine learning and artificial intelligence models 130, trained at least to determine adjustments 131 to outcomes of the primary simulation model 123. The present invention may further include any other component 120 to be used in iteratively modeling agricultural datasets 104 as described in the process 100.

These data processing components 120 are configured to generate output data 150 that may take many different forms. Output data 150 may include one or more outcomes 152 of an agricultural process 102, and these outcomes may further include derivatives or enhancements such as a predictions 154, forecasts 156, and recommendations or management action 158.

FIG. 2 is a flowchart illustrating steps in a method 200 for performing the multi-step iterative modeling process 100, according to certain embodiments of the present invention. Such a process 200 may include one or more functions, mathematical models, algorithms, artificial neural networks, other artificial intelligence and machine learning processes, and data processing techniques for the data processing components 120 that execute the iterative modeling approach of the present invention.

The method 200 begins at step 210 by ingesting, receiving, requesting, predicting, or otherwise obtaining input data 110 that is relative to an agricultural process 102 to be simulated. The method 200 then derives predictive variables 106 from this input data 110 at step 220. This identification of predictors 106 may be based on knowledge of the agricultural process 102, an evaluation of the types of input data 110, or by some other approach which aids in determining which variables are most relevant to the agricultural process 102.

The method 200 then develops the primary simulation model 123 for the particular agricultural process 102, at step 230. The primary simulation model 123 produces simulated outcomes, from which observations 125 that validate outcome are identified at step 232, and for which errors are calculated using these validating observations 125 at step 234. Additionally, the method 200 identifies combinations 126 of predictors 106 at step 236 that support these observations 125 to determine how to adjust outcomes in later steps.

The method then develops a correction model 128 to identify adjustments to the primary simulation model 123 at step 240. The method applies these adjustments at step 250 to the primary simulation model 123, and uses predictive variables 106 that are analogous to, or similar to, those used in the primary simulation model 123, in order to produce modified outcomes based on the validating observations 125, combinations 126 of predictors 106, and error calculations. This induces an altered response from the primary simulation model 123 at step 260, which is intended to reduce the overall errors for the eventual outcome of the agricultural process 102.

This sequence of interoperation between the models is repeated iteratively in the method 200, as shown at step 270, until errors in the primary simulation model 123 reach an apparent minimum for the desired agricultural process 102. The present invention then generates output data 150 from the primary simulation model 123 representing outcome(s) of the agricultural process 102, at step 280.

As also noted above, while there are any number of ways in which the iterative modeling process 100 can be applied, it is most easily explained using specific examples.

### Example 1/Part A

In a first simplified example, a dataset 104 to be used in modeling an agricultural process 102 contains the location, plant date, and maturity date of a crop across a range of situations, along with metadata indicating the ‘relative maturity’ rating of the specific cultivar of the crop being grown in each situation. In this example, the objective is to use this dataset 104 to develop a model that predicts the amount of crop growth on a daily basis across the range of situations represented in the dataset 104, in spite of the fact that no observations of the growth of the crop during its actual lifetime (the time between planting and maturity) are available.

To start the multi-step iterative modeling process 100, the present invention selects a set of daily environmental predictors 106 that are expected to have some influence on the daily rate of growth for the crop. These predictors 106 might be selected based on expert knowledge of the problem at hand, the findings of previous research related to the problem at hand, through statistical analysis of aggregate metrics of environmental conditions over the locations and periods of the data points in the observed dataset 106 of the problem to be modeled (the planting and maturity dates, in this example), or simply through trial and error (by repeating the end-to-end process with different predictor sets, and selecting the predictor set that results in the smallest error). For example, daily minimum and maximum air temperatures are often used as predictors 106 of crop growth in traditional growing degree day (GDD) models of crop growth. If a preconceived notion of the relationship between the selected predictors 106 and the rate of crop growth is available, this relationship can be provided as an initial guess at what the true relationship is (i.e., what the primary simulation model 123 is trying to determine). However, even using an entirely random (but consistent) metric of what the crop's growth response will be to a given set of predictors 106 (for each situation and day), an initial ANN can still be trained to replicate this first-guess at the form of the primary simulation model 123. This ANN shall be referred to as the ‘growth’ ANN (or, a primary simulation model 123) in the follow-on discussion, although its form will change (relative to the first-guess form) as the multi-step iterative modeling process 100 of the present invention is applied.

Given the output of this growth ANN 123 for each situation-date, the accumulation of the growth metric it produces as output can be calculated over the course of the growing season, for each situation. These daily growth metric values can be used to calculate an accumulated metric value that best corresponds to the value at maturity, using linear regression for instance. This accumulated metric value may be dependent on relative maturity, or other factors, as desired. For instance, an accumulated metric value of 1000 might correspond to maturity for one relative maturity classification (call it class ‘A’), while an accumulated metric value of 1200 might correspond to maturity for another relative maturity classification (call it class ‘B’).

Once the accumulated metric values that best correspond to crop maturity across the range of situations have been determined, the differences between the 1) accumulated metric values in each situation on the observed date of maturity and 2) the accumulated metric value identified as best representing the date of maturity across all situations, can be calculated. For instance, an accumulated metric value of 1100 might be noted on the observed date of maturity for a particular situation of a class ‘A’ cultivar. Comparing that accumulated metric value to the previously-identified ‘best’ accumulated metric value of 1000 (for relative maturity class ‘A’) as an indicator of maturity, it is apparent that 100 too many units of the chosen metric have been accumulated between the planting and maturity dates in this particular situation. For the sake of continued discussion herein, this manner of looking at the differences will be referred to as the ‘absolute difference’ approach. Alternatively, the situation could be looked at as having accumulated 10% too many growth metric units. This manner of looking at the differences will herein be referred to as the ‘relative difference’ approach. Both approaches are acceptable ways of evaluating the error, provided the follow-on steps in the multi-step iterative modeling process 100 are treated appropriately, as detailed below.

After the error, or differences, for each situation have been determined as per above, the multi-step iterative modeling process 100 requires that the problem now be ‘turned on end’. The objective at this stage of the process 100 is to find adjustments 131 that can be made to the growth ANN's response to particular sets of environmental conditions (via the input predictors 106) that will reduce the average error 129 as measured across all situations represented in the planting and maturity date dataset 104. One way of doing this is to create a separate ‘correction’ ANN (or, correction model 128), where the target values for each situation, and each date, are set to a value that is dependent on the error 129 previously identified for each situation.

In the event where the errors 129 are looked at in terms of percentages (the ‘relative difference approach’), a ‘target adjustment ratio’ can be identified for each situation. (Note that the word ‘target’ as used herein refers to the desired, or targeted, output of the primary model for a given set of predictor values.) In the example above, where an accumulated growth metric value of 1000 has been identified as being indicative of maturity for a class ‘A’ cultivar, and where in the particular situation of the example an actual accumulated growth metric value of 1100 was noted on the actual date of maturity, this ‘target adjustment ratio’ could be set to a value equivalent to 1000/1100, or approximately 0.909. This means that adjusting the growth ANN 123 such that it produces growth metric responses that are 90.9% as large as the values it is currently producing would be beneficial (for this particular situation). The same (or analogous) growth ANN predictor values 106 for each date for this situation can then be thrown into a pool of training data for a ‘correction’ ANN 128, along with an associated target value of 0.909 for each date associated with this situation.

After carrying this step out across all situations, for all dates, the resulting dataset 104 can be used to train this correction ANN 128. Since the ANN training process seeks to minimize the collective error between the responses it produces for each situation-date and the provided target data for those same situation-dates in the training pool, the training process will preferentially adjust the correction ANN's response (i.e. its prediction of the target adjustment ratio for each situation-date) on situation-dates where such an adjustment will reduce the collective errors 129 associated with the growth ANN's output. Stated more simply, if two situation-dates in the training pool of data for the correction ANN 128 have like values for the full set of input predictors 106, but have differing target adjustment ratios of 0.9 and 1.1, the correction ANN training process may see little potential to reduce the collective error by making an adjustment to the response it produces for that particular combination of input predictor values. In other words, it will likely produce a mid-range response between these two target values, or close to 1.0 (effectively meaning it will make no change in the growth ANN's corresponding response). On the other hand, if those same situation-dates each had target adjustment ratios of 0.9, then the training process for the correction ANN 128 might see an opportunity for an adjustment that can be made in the growth ANN's response to the particular combination 126 of input predictor values that will be beneficial in both situation-dates, thus reducing the collective error.

Once the correction ANN 128 has been trained, it will produce an output value for each situation-date that is akin to the target adjustment ratio that was used in its training. For situation-dates where the target adjustment ratios in the correction ANN training dataset, for a particular combination 126 of input predictor values, preferentially favor an increased or decreased response (growth metric value) out of the growth ANN 123, the correction ANN 128 output may vary substantially on either side of 1.0. When there are as many situation-dates favoring an increased growth ANN response for a particular combination 126 of predictor values as there are situation-dates favoring a decreased response, the output of the trained correction ANN 128 for those situation-dates may be very close to 1.0. This indicates that neither increasing or decreasing the growth ANN's response for that particular combination 126 of predictor values will be likely to decrease the collective error across all situations.

In any case, once a trained correction ANN 128 is available, the predictor values 106 for each situation-date can be run through this correction ANN 128. The output of the correction ANN 128 for each situation-date (at least in this example where we're using target adjustment ratios) will be a multiplier that can be applied to current output of the growth ANN 123 for that same situation-date in order to create a new target value for that same situation-date. For example, if the growth ANN 123 had produced a response of 10 (growth metric units) for a particular situation-date, and the correction ANN 128 produced a response of 1.5 for that same situation-date, the growth ANN 123 target value for this situation-date would be reset to its original output (10) multiplied by this target adjustment ratio (1.5), such that the new target value for the situation-date when retraining the growth ANN 123 would now be 15.

Carrying out this target value adjustment process across all situation-dates in the dataset 104 results in a revised pool of training data that can be used to produce (train) a new growth ANN 123. This revised pool consists of the same (or analogous) predictor values 106 as the original, but with the target values for each situation-date modified as described above. Using this revised pool of training data, a new growth ANN 123 can be developed, after which the process of developing a new corrective ANN 128 and another pool of revised training data for yet another new growth ANN 123 can be repeated. During the initial iterations, the error in the predicted maturity dates from the successive growth ANNs 123 should decrease. After some number of iterations, the process 100 will be unable to find situation-dates where beneficial changes to the growth ANN's response can be made, resulting in the overall error asymptoting toward some plateau in the average error.

These remaining errors are often representative of aspects of the crop's growth that do not appear to be attributable to the selected predictor variables 106. In such a case, decreasing error further will generally require selection of more or different predictor variables 106 and repeating the entire process from the beginning with an altogether new growth ANN 123. (It should be noted that if there is error in the input predictor values themselves, reducing those errors can also result in reduced error in the output of the final growth ANN 123.) Another possibility with respect to these remaining errors is that the iterative model development process has settled into a growth ANN 123 that yields a local minimum in the error, as opposed to one that yields a global minimum in the model's error. Which is the case in any given application of this technique can be difficult to determine. Implementation practices that can reduce the probability of the approach settling into a form that yields only a local minimum in the errors 129 include repeated random sub-sampling of the dataset 104 during the training process, applying different initial guesses of the form of the growth ANN 123 during the training process, and also detecting and preventing physically unrealistic responses from the growth ANN 123 for a given set of input predictor values 106 (i.e., guiding or constraining the training process using scientific reasoning).

The entire multi-step iterative modeling process 100 above can be summarized in a highly simplified example, depicted in the three charts of FIGS. 3A, 3B and 3C. Note that while the corresponding discussion will refer to steps in the process 100 as if they would be carried out with ANNs, it is to be understood that this illustrative example performs a similar multi-step iterative modeling process 100 on a very small and simple dataset without actually using ANNs. For this simplified example, it is assumed that:

The dataset 104 consists of two separate ‘cases’ (or ‘situations’, in the terminology used above): Case A and Case B;
Case A experiences the exact same environmental conditions on each of days 1, 2, 4 and 5;
Case B also experiences the exact same environmental conditions on each of days 1, 2, 4, and 5, but where those conditions differ from those of Case A on those same days;
Case A and B have identical environmental conditions on days 3 and 6 of their growing seasons, where those conditions are different from those of either Case A or Case B on days 1, 2, 4 and 5;
the crop that is being considered in both cases grew from planting to maturity in 6 days;
Case A is of a relative maturity that requires 40 accumulated growth metric units to evolve from planting to maturity, whereas Case B is of a relative maturity that requires only 20; and
the process is started assuming 5 growth metric units are accumulated each day, in each case, irrespective of environmental conditions (i.e. the form of the initial growth ANN 123 would be such that it returns a growth metric response of 5 regardless of the combination of input predictor values it receives).

In FIG. 3A, it is evident that the growth metric response for the initial iteration (1, denoted as e.g. “Case A (1)”) has been set to a value of 5.0, for both cases, for all six days, as per the assumptions above. In FIG. 3B, it is evident that the iteration (1) targeted adjustment ratio is set to 1.33 (=40.0/30.0) for Case A, and to 0.67 (=20.0/30.0) for Case B, for all six days. These targeted adjustments 131, as well as the associated environmental conditions, are used to train a correction ANN 128. The output of the trained correction ANN 128 (FIG. 3C) matches that which was targeted for days 1, 2, 4 and 5, for both of Cases A and B. However, since the environmental conditions for Cases A and B are identical on days 3 and 6, and the targeted adjustments are in opposing directions (increasing for Case A, but decreasing for Case B), the trained correction ANN 128 ‘realizes’ that it is unable to accommodate the targeted adjustments 131 to the growth metric response associated with that particular set of environmental conditions. Instead, it settles on an adjustment ratio of 1.0, or halfway between the 1.33 and 0.67 adjustment ratios that were targeted for those days. This is shown in FIG. 3C, where it is apparent that the output adjustment ratios of the correction ANN 128 for days 3 and 6 settle at a value of 1.0, whereas the output adjustment ratios for the other days match those which were targeted for both of Cases A and B.

Under the multi-step iterative modeling process 100 outlined above, these output adjustment ratios from the correction ANN 128 can be multiplied by the first-pass' growth ANN metric values for the associated cases and dates (situation-dates). This results in the iteration (2) growth response metrics as shown in FIG. 3A. It is immediately evident that the growth metrics for days 1, 2, 4 and 5 have been adjusted in the desired direction for both cases (to achieve the desired accumulated growth metric values of 40 and 20, for Cases A and B, respectively), but that the growth metrics for days 3 and 6 are unchanged.

Repeating the steps above produces yet another set of output adjustment ratios that can be used to further modify the growth response metrics for each case and day in iteration (3). This entire process 100 can be repeated until no further significant adjustments 131 are made to the growth ANN's output metric values between successive iterations (meaning that the correction ANN is producing values very near to 1.0 for all situations). Once this occurs, the relationship between the provided environmental conditions and the growth response of the crop (as indicated by the corresponding growth metric values) is fully described by the associated growth ANN 123 in this manner, at least insofar as the input predictors are able to ‘explain’ the crop's growth.

### Example 1/Part B

A variant on Part A of the first example is to use the previously-discussed ‘absolute difference’ approach instead of the ‘relative difference’ approach applied above. In this approach (Part B), the absolute difference between the situation-specific accumulated growth metric value at maturity vs. the average accumulated growth metric value at maturity across all similar situations can be (e.g.) divided by the number of days between planting and maturity. The result is an adjustment 131 that could be added to the daily growth metric that was produced by the growth ANN 123 of the previous iteration, for all of the days between planting and maturity for that specific situation, in order to make the accumulated growth metric at maturity for that specific situation match that which is desired. Once a correction ANN 128 is trained on this adjustment data 131, it will produce an absolute adjustment that can be made to the growth ANN's output for the specific combination 126 of input predictor values for each situation-date. These adjustments 131 can be applied to the current output of the growth ANN 123 for all situation-dates, creating new target values that can be used in combination with the original growth ANN input predictor values 106 in order to train a new growth ANN 123. As in the first example, this process of growth ANN training, followed by the development of a correction ANN 128 and adjustment 131 of the growth ANN's target values for a next iteration, can be repeated to convergence (i.e., to an asymptoting of overall errors in the growth ANN's output).

### Example 2

The technique applied in the first example can be expanded so as to automatically develop separate ANN models of interdependent problems from a common dataset 104. For example, if the observed end-of-season data elements of the first example are changed to be the harvest date and grain moisture on that date (instead of the maturity date), it is possible to add an additional outer iteration loop that coordinates back-and-forth iteration between the development of a growth ANN 410 to simulate the pre-maturity portion of the cropping cycle, and a ‘drydown’ ANN 420 to simulate the post-maturity drying of the crop's grain. FIG. 4 is a flow diagram illustrating this process 400 of automatically developing separate models of interdependent problems from a common dataset 104 according to the present invention.

In such a situation, a simple model for working backwards from the harvest date and grain moisture to estimate the date on which the associated crop reached maturity can be used to begin the process. Given this estimated maturity date for each situation, development of a growth ANN 410 can proceed as per the first example. Once a growth ANN 410 has been developed, the maturity dates produced by the growth ANN 410, metadata representing the typical moisture content at maturity, and the actual harvest date and grain moisture data available in the dataset 104, can be used to develop a drydown ANN 420 in a similar manner (since the drydown problem has the same characteristic of having a cumulative dependence on conditions between the two dates). Once the drydown ANN 420 has been developed, it can be integrated backward from the harvest date and moisture again, yielding a revised (theoretically improved) estimate of the date of maturity for each situation. This revised estimate of the maturity date can then be used to train a new growth ANN 410, followed by a new drydown ANN 420, etc. The process of successive adjustment and retraining of the growth and drydown ANNs 410 and 420 can be repeated until errors from both ANNs have plateaued. The end result will be separate growth and drydown ANN models 410 and 420 that can be applied independently as desired, or in concert with one another. The growth response of corn to a few randomly-selected environmental parameters, as determined through a real-world application of the process 400 shown below in FIG. 4, is depicted in FIGS. 7 and 8A-8D.

A logical question would be how do these example results compare to what has been previously determined via prior art approaches within the agronomic research community? FIG. 5 is a plot 500 of data points depicting the growth response function determined using the present invention 100. This particular plot represents the growth response as a function of temperature. The dots that make up the plot each represent one situation-date, as referred to in the discussion above. The fact that there is vertical spread to the growth response at any given temperature is indicative of the fact that some of the other predictive factors act to further modulate growth at any given temperature. FIGS. 6A, 6B, and 6C are plots 600 of comparable data points from prior art approaches, depicting the growth response function as determined from GrowingDegree Days 610 (GDDs, FIG. 6A), Crop Heat Units 620 (CHUs, FIG. 6B), and the General Thermal Index 630 (GTI), respectively, for the vegetative (GTIv) and reproductive (GTIr) (FIG. 6c) stages of corn growth. From these figures, it is evident that the growth responses 610, 620 and 630 from these traditional methods fall into the same general range as the growth response function as determined by the present invention 100. (Note that the arrangement of the black dots in the GTI comparison (FIG. 6C) looks different from the others, in that they fall along a couple of very specific lines representative of the separate GTIv (vegetative stage) and GTIr (reproductive stage) formulas. Since these GTI formulas use the daily average temperature as the only input, rather than both the daily minimum and maximum temperatures as the others do, there is no ‘spread’ in the calculated growth response for a given daily average temperature.) While additional research would be required to demonstrate whether the growth response function of the present invention 100 yields consistently better predictions of corn growth than the more traditionally-derived GDD, CHU, and/or GTI formulas, the shape of the envelope of growth responses (in FIG. 5, and in the backgrounds of FIG. 6) as a function of temperature from the present invention does at least appear more natural (smooth) than those from the prior art approaches.

### Example 3

The technique as discussed in the preceding examples uses ANNs for both the primary and corrective models 123 and 128 in the iterative model development process. While this is a powerful implementation of the technique, ANNs are not a necessary requirement for applying the general concept. Similar steps can be taken to develop models using simpler underlying models, as demonstrated by the simple illustrative example of FIG. 3. For example, it is possible to select a predictive variable 106, the time-varying values of which impact some arbitrary process to be modeled. Starting with a flat response function (i.e., a model that produces the same output irrespective of the value of the predictive input variable 106), the output values, as aggregated to be comparable with a validating data point, can be compared to the validating data point. The resulting information on differences between the predicted (output) values and the validating data point can then be assigned back to ‘buckets’ associated with discrete subspaces within the input predictor space, across all situation-dates. In the simplified example of FIG. 3, the (identical) environmental conditions on days 1, 2, 4, and 5 for Case A could fall into one bucket, days 1, 2, 4, and 5 for Case B could fall into second bucket, and days 3 and 6 for both of Cases A and B into a third bucket. Thus, there are only 3 possible sets of environmental conditions in this example (which is obviously an entirely unrealistic expectation for real-world environmental conditions), yet the example is still useful for illustrative purposes. The contents of these buckets for each discrete subspace of input predictor values 106 can be used to identify the direction in which the response function for input predictor values 106 in that subspace can be moved in order to decrease errors in the aggregated output of the model as measured against the validating data points. Successive repetition of this process, making small adjustments to the form of the response function in each successive iteration, will eventually lead to a final response function associated with the selected predictive variable 106 that minimizes error between the aggregated output of the model and the validating data points.

If the problem at hand is known to have dependence on multiple predictor variables 106, the technique can be continued by moving on to the next predictor variable 106 and repeating the entire process (but where the previously-identified impacts of preceding predictor variables 106 are also included in the aggregated output). Once this has been repeated across all input predictor variables 106, the entirety of the process 100 can be repeated again (i.e., starting back with the first predictor variable 106, but accounting for the previously-identified impacts of all the predictor variables 106 from the previous iteration when aggregating the output to compare against the validating data points), and again, until no further reduction in errors is achieved.

### Example 4

In a fourth example, a dataset 104 to be used in modeling an agricultural process 102 contains the locations of fields, an indicator of actual disease incidence in those fields, and information regarding the timeframe during which the disease incidence data are valid in each field. This timeframe could be as broad as the encapsulating plant date and maturity date for each location, for example, though the process is apt to produce better results if the timeframe during which the disease could have occurred is provided (e.g., if a disease is only able to infect a plant after flowering, limiting the timeframe for each location to the post-flowering time period is likely to be beneficial to performance).

Unlike the example of a growth model, the occurrence of a disease is not so easily broken down into a daily response that can then be summed over the period of interest to yield a total response. The occurrence or non-occurrence of a disease is likely a more complex function of the conduciveness of environmental conditions over time. In particular, unlike the crop growth case, the cumulative risk of disease occurrence may be completely reset again and again as conditions that are detrimental to infection by a pathogen occur (whereas, conversely, a plant can't ‘ungrow’).

To start the iterative modeling process 100 in this case, the present invention might select a set of e.g. hourly environmental predictors 106 that are expected to have some relationship to the conduciveness for a particular disease to occur. These input predictors 106 can be selected in any number of ways, as per earlier discussion. Though not necessary, if a preconceived notion of the relationship between the selected predictors 106 and the conduciveness to disease incidence is available, this relationship can be provided as an initial guess as to what the true relationship is (i.e., what the ‘primary model’ 123 is trying to determine). Providing such an initial guess can both speed the ANN training process, and potentially help to prevent the training process from settling into local minimums (as opposed to global minimums) in model error. The ANN trained to this initial guess (whether random or informed) as to the conduciveness of environmental conditions to disease development shall be referred to as the ‘conduciveness’ ANN in the follow-on discussion, although its form will again change as the iterative modeling process 100 of the present invention is applied. Note that this ‘conduciveness’ ANN is the ‘primary model’ of this example.

Given the output of this conduciveness ANN for each location-hour, a method for combining the location-hour information into a cumulative risk of disease incidence at the location over time must then be applied. In the prior art, this method is typically either some threshold duration of continuous conduciveness to disease development, or some other additive function for accumulating (and regularly resetting) the conduciveness information across successive times. In this ‘Part A’ example, it will be assumed that the method by which the cumulative disease risk is to be calculated from the location-hour conduciveness data output by the conduciveness ANN is already defined. Applying this predefined method to the hourly conduciveness data over some period of time prior to each hour in the dataset 104 at each location will yield a cumulative risk of disease incidence at each hour at each location.

The accumulated disease risk data that are so-defined for any given location can then be compared against the actual disease incidence data. Through this comparison, an accumulated disease risk threshold that yields the best performance in terms of predicting the actual disease incidence data can be determined. At this point, the difference between the maximum accumulated disease risk and the disease risk threshold so-defined, for each location, can be calculated. The input predictors 106 for each time and location can then be thrown into a new training pool for a ‘correction’ ANN 128, with associated target values of e.g. (a) some number slightly less than 1.0, (b) 1.0, or (c) slightly greater than 1.0, depending upon whether the accumulated disease risk is (a) overstated, (b) accurately stated, or (c) understated relative to the actual disease incidence observed. Once the pool of ‘correction’ ANN 128 training data has been developed, the correction ANN 128 can be trained as per previous examples, and the output of the correction ANN 128 for each hour at each location can be multiplied by the conduciveness ANN's current target values for each hour at each location in order to produce adjusted target values. These adjusted target values, and the original input predictors, can then be thrown into a pool of training data for a revised ‘conduciveness’ ANN, and the conduciveness ANN can be retrained.

Following previous examples, the retrained conduciveness ANN's output can be applied in the aforementioned method for combining the location-hour conduciveness information into a cumulative risk of disease incidence at each location over time. This cumulative disease risk output can be compared against actual disease incidence data once again, at which point a new threshold value for best discriminating between disease occurrence and non-occurrence can be calculated. The process of developing and retraining a ‘correction’ ANN 128 can then be repeated, as per above, and the process continued until no further improvements in the cumulative disease risk prediction relative to the actual disease incidence data are noted between successive iterations.

Note that it would be possible to skip the development and training of the ‘correction’ ANN 128 in this example, and instead just multiply the ‘conduciveness’ ANN's current target values by a number slightly less, equal to, or slightly greater than 1.0, depending upon how the cumulative disease risk at each location compares against the actual disease incidence. However, in all likelihood, the disease conduciveness ANN's response does not need to be changed for the vast majority of times and locations in order to result in an improved cumulative disease risk prediction. Using the correction ANN 128 allows the process to explore the entirety of the dataset 104, across all times and locations, for targetable opportunities where changing the disease conduciveness ANN's response to certain combinations 126 of input predictor values is most apt to improve performance of the resulting cumulative disease risk prediction as measured against actual disease incidence data. Contrast this to the brute force approach of the alternative, where the conduciveness ANN's target values are adjusted directly and equally (in a proportional sense) across all hours in the dataset 104 for any given location. It is possible that target value adjustments in opposing directions in the resulting training dataset will occur in approximately equal proportions for combinations 126 of input predictor values that have no bearing on disease risk, in which case the end result of the entire process may be essentially the same regardless of whether the correction ANN 128 is applied vs. adjusting the target values directly. However, the latter seems likely to be slower to converge, and more apt to fall into local minimums in error during the iterative training and retraining process than if a correction ANN 128 is used (among other potential issues).

Also noteworthy is that it may in fact be advantageous to the correction ANN training process to only use a targeted subset of the location-hour conduciveness data. For example, if disease does actually occur in a field, and the maximum cumulative disease risk that is calculated across all hours for a given location is also indicative of disease, then data for all of the other hours with cumulative disease risks less than the maximum do not yield any clear indication about the conduciveness for disease under those conditions. It may only take one occurrence of a high cumulative disease risk for the disease to actually occur, such that so long as there is one such hour with an adequate risk present, then we cannot definitively say that any other hours in the dataset 104 for the given location would not have also resulted in an actual incidence of the disease. As such, it may be desirable not to include those hours in the correction ANN retraining pool for the next iteration, though excluding data in this manner can result in lopsided training datasets that may pose other problems.

### Example 5

As with Example 2 vs. Example 1, it is possible to further improve disease prediction through the intertwined training and retraining of two different primary models within an ‘outer loop’. For instance, following Example 4, instead of defining the method by which the disease conduciveness ANN's hourly output for each location is translated into a cumulative disease risk, a second primary ANN for performing this translation could be developed. In this case, the second primary model (labeled the ‘cumulative risk’ ANN in this example) can be developed during the same process under which the ‘conduciveness’ ANN is developed. In this example, an initial version of the cumulative risk ANN can be trained to replicate the prescribed method for aggregating hourly conduciveness data into a cumulative disease risk for each hour at each location. The input predictors 106 to the cumulative risk ANN would most likely be the hourly outputs of the conduciveness ANN for each of the ‘N’ previous hours, as well as potentially some metadata-based predictors 106 that are expected to improve the ANN's ability to correctly discriminate. Differences between the ANN-based cumulative disease risk and the actual disease incidence data can then be assessed in a fashion similar to Example 4, and a correction ANN 128 developed in much the same way. However, rather than applying the correction ANN's output values back to the conduciveness ANN's target values, they could instead by applied back to the cumulative risk ANN's target values. This cumulative risk ANN can then be retrained, and the process 100 repeated until successive versions of the cumulative risk ANN exhibit no further reductions in error. At that point, the cumulative risk ANN can be held fixed (similar to how the prescribed method for defining a cumulative risk from hourly conduciveness data wasn't changed in Example 4), and the process 100 of Example 4 can be repeated to adjust the conduciveness ANN's output for each hour at each location. Once iterated to convergence again (i.e. to a minimum in errors), the process 100 can be focused back on adjusting the cumulative risk ANN again, and so forth. The entire process 100 can be repeated until no further reductions in error 129 are seen between successive iterations of this ‘outer loop’, at which point a two-step ANN-based model for disease prediction will be finalized (two-step meaning that a conduciveness ANN is first applied to each hour, and a second step cumulative risk ANN then converts this hourly conduciveness data into cumulative risk data).

### Input Predictors: Weather Conditions Data

As discussed earlier, input data 110, including variables 106 describing one or more of weather conditions 111, soil conditions 114, crop and seed properties 115, other environmental factors 117, and process-specific metadata 116 over a period of time, are required for both the model generation step and the subsequent application of that model.

Weather conditions data 111 might include, for example, field-level weather data 112 that occurred during a growing season, including both in-situ and remotely-sensed observations as well as assessments of weather conditions based on a combination of weather information resources. Weather conditions data may also include climatological information, and/or modeled weather data such as extended-range weather forecasts 113.

In-situ weather data may be available from one or more weather observing sensors or stations located in or near to the locations of fields used in either the initial model development or subsequent model application steps. Observational weather data from remote-sensing platforms are also available in many parts of the world, and can provide higher-resolution data with respect to certain aspects of the weather occurring at a given location over a given timeframe. Modeled weather data may be provided from numerical weather prediction (NWP) models, and may be combined with data from surface weather observing networks and/or weather radars and satellites, in order to create the best reconstruction of the weather conditions for any particular location and timeframe to be analyzed.

There are numerous NWP models available within the weather industry, and any such models may be used as sources of weather condition data for the present invention. Examples of NWP models at least include RUC (Rapid Update Cycle), WRF (Weather Research and Forecasting Model), GFS (Global Forecast System), and GEM (Global Environmental Model). Such meteorological data may be received in real-time, or after-the-fact, and may come from a number of different sources, such as from the European Centre for Medium-Range Weather Forecasting (ECMWF), Meteorological Services of Canada's (MSC) Canadian Meteorological Centre (CMC), as well as the National Oceanic and Atmospheric Administration's (NOAA) Environmental Modeling Center (EMC), among others. Additionally, internally or privately-generated “mesoscale” NWP model forecasts can be used. Such mesoscale models are typically specialized for forecasting weather with more local detail than is often found in the data provided by government weather prediction centers. These mesoscale models can be very useful for characterizing how weather conditions may vary over small distances and over small increments of time. The present invention may be configured to ingest data from all types of NWP models, regardless of whether publicly, privately, or internally provided or developed.

### Input Predictors: Soil and Environmental Data

Input data 110 may also include information related to the soil conditions 114 or other environmental factors 117 impacting the problem to be modeled. Soil conditions data 114, including soil temperature and moisture profiles, can be obtained in a manner similar to weather condition data 111 (as discussed above). Sensor-based in-situ soil temperature and moisture data, at any given depth or over a range of depths, can serve as input predictor data 106. (If the goal of developing the model is to later use it for real-time forecasting, however, a different data resource may be needed to cover timeframes that are in the future.) Remotely-sensed soil conditions data can also serve as input predictor data, with the same caveat. Due to both the cost and maintenance needs associated with sensing soil conditions, and the common need to also have forecast data of the same conditions, one appealing source for such data are models commonly referred to as ‘land surface models’ (LSMs).

Land surface models simulate the interactions between the weather conditions, the vegetation, and the soil. Such simulations may include, but are not limited to, simulation of runoff and infiltration of precipitation with respect to the soil profile; drainage, vapor diffusion, capillary action, and root uptake of moisture within any number of layers within a soil profile; vertical diffusion and conduction of internal energy (heat) into, out of, and within the soil profile; plant growth and transpiration, including the impacts of weather and soil conditions on the properties and processes of this vegetation; and direct exchanges of moisture between the atmosphere and the soil (and plant) surfaces via evaporation, sublimation, condensation and deposition, among other processes.

It is to be understood that existing land surface models may provide the soil conditions and other environmental data for the modeling approaches of the present invention, and that existing land surface models may be customized for particular agricultural situations. Existing land surface models may be customized in many different ways, to produce particular output data streams as required by the situation being modeled. For example, a land surface model may be customized to simulate a water deficit and its impact on crop development. A land surface model may also be configured to analyze different vegetation/crop(s), and at different growth stages/heights or under different levels of stress. Other examples of possible analyses include a simulation of soil-water characteristics for an understanding of current moisture conditions in a soil system, a simulation of moisture flows emphasizing characteristics such as water transport/distribution within the soil column, horizontal variances with soil, canopy wetness, and the impact of prior applications of artificial precipitation, and a simulation of an available water holding capacity for minimizing losses of water and nutrients in the soil system.

Commonly-used land surface models include the NOAH community land surface model, originally developed jointly by the National Centers for Environmental Prediction (NCEP), the Oregon State University (OSU), the United States Air Force, and the National Weather Service's Office of Hydrology (OH). They also include the VIC model, or Variable Infiltration Capacity model, developed by the University of Washington's Land Surface Hydrology group, and the Mosaic model, developed by the National Aeronautics and Space Administration (NASA). Another example is the CLM model, or Community Land Model, a collaborative project between divisions and groups within the National Centers for Atmospheric Research (NCAR). Numerous other land surface models are available for both research and commercial applications.

### Input Predictors: Process-Specific Metadata

As discussed above, process-specific metadata 116 may include information reflecting actual performance, realization, or implementation of one or more of crops, plants, fields, soils, and facilities in a desired agricultural process to be modeled. This metadata 116 may include more in-depth crop and seed information, for example, crop and seed metadata that including relative maturity rating, dry-down characteristics of the variety of crop or seed used in a particular field, pest and disease susceptibility or resistance, whether a crop is irrigated or non-irrigated, type and origin of seeds (such as, for example, genetically modified or non-genetically modified, and company source), amounts of additional applied minerals (e.g., nitrogen, potassium), and amounts and timing of any fungicides, herbicides, pesticides, plant growth regulators, and desiccants. Such metadata 116 may also include soils metadata such as information relating to previous crop grown on or in the soil, soil composition, presence of surface and/or subsurface drainage, nutrient availability within the soil profile, rate of water movement in both a lateral and vertical direction, presence of materials such as salts in soil strata, and farming practices such as the type(s) of tillage performed in the field, and when.

Process-specific metadata 116 might also include dynamic metadata that changes over time. For instance, photoperiod may be a factor in a particular plant process. Photoperiod changes from one location to another, and also changes over time at any given location. Photoperiod and/or the rate of change of photoperiod are often important factors in triggering transitional events in a plant's life cycle.

While simulation of a particular process will perhaps be the most common application of the present invention, it also has utility as an aid in improving understanding of the factors that influence the process to be simulated. For instance, once a trained model has been developed, one could specify hypothetical scenarios in which most input predictor values 106 are held steady, but where one predictor (or some small subset of predictors) is varied, and then analyze or visualize how the model responds to variations in the specific predictor(s). One could likewise apply the model to a large set of input predictor value combinations (such as might be present in the training dataset, for instance), and then look for patterns in how the model output may cluster or vary as a function of those input predictor values 106. An example of such an application is provided in FIG. 7, which is a plot 700 of data points illustrating the impact of soil moisture on growth response according to the present invention. In FIG. 7, which is based on the same dataset as FIGS. 5 and 6, each dot represents a particular date in a particular test plot of the training dataset. In these figures, the present invention has been trained to simulate the growth of the corn plant based on a combination of input predictors that includes daily minimum and maximum air temperatures, daily total solar radiation, soil temperature and moisture data from a land surface model, photoperiod, relative maturity, and a few other variables. In the plot 700 of FIG. 7, the abscissa represents the daily average air temperature, the ordinate represents the growth rate of the corn plant, and the shading of the dots represents soil moisture in a 40-70 cm depth range, with soil moisture values near 0.0 representing soil moisture near the permanent wilting point, and values near 1.0 representing soils with moisture near field capacity.

In the example of FIG. 7, it is apparent that there is no clear pattern in the dot shading within the envelope of daily growth responses at temperatures below about 65 degrees F. However, as the daily average air temperature warms beyond that, the dot shading begins to organize into higher rates of growth in moist soils as compared to in drier soils. In other words, the model developed using the present invention is indicating that soil moisture impacts the growth rate of the corn plant during warm temperatures. The nature of that impact is such that growth is slower in warm, dry conditions than it is in warm, wet conditions. This is a property of the corn plant that is already known to the scientific community through previous research, but the present invention is able to help quantify the magnitude of that effect, and can be applied to other crops for which the body of prior research-based knowledge is much more limited.

A similar example in FIG. 8A, FIG. 8B, FIG. 8C and FIG. 8D can be useful for illustrating one of the complexities of interpreting the product of the present invention. Specifically, that is the oft-encountered problem in science that correlation does not necessarily imply causation. In the example of FIGS. 8A, 8B, 8C and 8D, the daily average solar radiation (FIG. 8A), the daily photoperiod (FIG. 8B), the day-to-day change in the daily photoperiod (FIG. 8C), and a ‘growth progress’ metric (0.0 representing planting, 1.0 representing maturity) (FIG. 8D) were all provided as input predictors 106 in the process 100 of developing a model for corn growth. Using the same display configuration as in FIG. 7, but for each of those four input predictors 106 instead, it is evident that there is similarity in the dot patterns across all four of these input predictors 106 (though the actual shading of the dots is inverted in some panels relative to others). The general pattern that is present in each is that the season progresses from left-to-right as the weather warms over the spring and early summer, and then from right-to-left as the weather cools again in the late summer and fall. Each of the graphs 810, 820, 830 and 840 appear to indicate that growth is faster for a given temperature during the first part of the corn life cycle than it is for the same temperature later in the corn life cycle. Alternatively, it could also be indicating that corn growth is simply more sensitive to temperature in the first part of its life cycle, which is known to be true from prior research performed by the scientific community. Determining which of these possibilities is actually the case in this situation would require a rather complex analysis into the specifics of this implementation of the present invention, and is not done here.

More to the point, however, this example illustrates how it can be difficult to attribute a clear pattern in the model's output to its underlying meaning. In this case, one could argue any of the following points (and potentially others) based on the four separate panels 810, 820, 830 and 840 of FIGS. 8A-8D: a) the corn plant grows faster for the same temperature when solar radiation is higher, b) the corn plant grows faster for the same temperature when the days are longer, c) the dependence of the rate of growth of the corn plant on the rate of change of the daily photoperiod is most pronounced when the daily change in photoperiod is large (positive or negative), or d) the corn plant grows faster for the same temperature during the first half of its life cycle than it does during the latter half of its life cycle.

Which of these possible findings are actually correct, if any? Since there is a relatively predictable relationship between all four of these input predictor variables 106 in this particular dataset 104, it is entirely possible that only one of these findings is correct (if any), and that the similar pattern shows up for the other input predictor variables 106 only because they happen to be directly relatable to the input predictor variable 106 that is the true driver of corn growth variability. This problem of determining causality in the presence of correlated predictors is not unique to the present invention, however. Numerous techniques for attempting to address this problem exist within the scientific community.

There are a broad range of problems to which the methodology of the multi-step iterative process 100 can be applied in order to develop detailed models of complex processes using observational validating data points that may be much more limited in scope. One example includes the development of crop growth models, as noted in the examples above, where crop growth is a function of crop properties and the ever-changing environmental conditions, and where validating data might only exist at a small number of points in time during the crop's life cycle in any particular location and season. A closely related application would be the application of the present invention for predicting the timing of (or between) events that are important to the producer of the crop, or that require some specific action be taken by the producer of the crop.

Another example is the development of crop drydown models, as also noted in the examples above, where the changes in crop moisture over time are a function of the crop properties and changing environmental conditions, and where validating observational data exist only at a small number of points in time during the crop drydown process for any particular location and season. Still another example is the development of crop water use models as a function of environmental conditions based on end-of-season total crop water usage. Yet another example is the development of leaching models as a function of environmental conditions based on drain tile flow data. Another example is the development of a nutrient utilization model as a function of growth progression and environmental conditions based on one or more scientific soil samples that measure mineral, organic matter, pH, and other soil contents and properties. Another example is the development of a yield prediction model as a function of growth progression, historical environmental conditions, forecast environmental conditions, climatological environmental conditions, and other meta and environmental data based on end of season or harvest yield data. Another example is the development of a disease impact model as a function of growth progression and environmental conditions based on a count of disease-related instances per plant or area.

As noted above, the present invention also contemplates that one or both of the primary simulation model 123 and the correction model 128 may include one or more layers of machine learning and artificial intelligence models 127 and 130, respectively, to continually analyze both the input data 110 and the outcomes of those models, to build comprehensive datasets that can be used to make improvements to simulations of the agricultural processes 102. For instance, the one or more layers of machine learning and artificial intelligence 127 and 130 can be applied to draw automatic associations and identify combinations 126 among the predictors 106 in the input data 110, and identify adjustments 131 to be made to outcomes of the primary simulation model 123 based on these combinations 126.

The present invention contemplates that many different types of artificial intelligence may be employed within the scope thereof, and therefore, the one or more layers of machine learning and artificial intelligence 127 and 130 may include one or more of such types of artificial intelligence. The one or more layers of machine learning and artificial intelligence 127 and 130 may apply techniques that include, but are not limited to, k-nearest neighbor (KNN), logistic regression, support vector machines or networks (SVM), and one or more neural networks as discussed above. Regardless, the use of artificial intelligence in the process 100 of the present invention enhances the utility of the primary simulation model 123 and correction model 128 by automatically and heuristically constructing appropriate relationships, mathematical or otherwise, relative to the complex interactions between variables 106 made available for the particular agricultural process 102.

The foregoing descriptions of embodiments of the present invention have been presented for the purposes of illustration and description. It is not intended to be exhaustive or to limit the invention to the precise forms disclosed, or potential applications discussed. Accordingly, many alterations, modifications and variations are possible in light of the above teachings, may be made by those having ordinary skill in the art without departing from the spirit and scope of the invention. It is therefore intended that the scope of the invention be limited not by this detailed description. For example, notwithstanding the fact that the elements of a claim are set forth below in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a sub-combination or variation of a sub-combination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptually equivalent, what can be obviously substituted and also what essentially incorporates the essential idea of the invention.

1. A method of improving crop yield for a future harvest, the future harvest being associated with a selected geographical area and a current growing season, the method comprising:
developing a primary model; and
utilizing the primary model to model a complex agricultural process associated with the crop yield for the future harvest,
wherein developing the primary model comprises a multi-step process for developing an optimized iteration of the primary model, the multi-step process comprising:
defining a first set of predictive variables, the first set of predictive variables comprising at least one predictive variable;
obtaining first and second validating observation values associated with the first and second geographical areas, respectively, and the first and second growing seasons, respectively;
determining a number of accumulation days for each of the first and second validating observation values and assigning for each accumulation day first and second guess values, thereby creating respective first and second sets of data for the first set of predictive variables, each of the first and second sets of data comprising data for a plurality of data points being associated with respective a first and second geographical areas and respective a first and second growing seasons;
utilizing the first and second sets of data with a first iteration of the primary model to obtain first and second aggregate solutions; AND
calculating errors in the first iteration of the primary model by comparing the first and second aggregate solutions with the first and second validating observation values, respectively,
wherein each error is one of an absolute difference or a relative difference.

2. The method of claim 1, wherein each of the first and second geographical areas is the selected geographical area, wherein each of the first and second growing seasons is different from the current growing season, and wherein the first growing season is different from the second growing season.

3. The method of claim 1, wherein each of the first and second growing seasons is different from the current growing season, and wherein the first geographical area is different from the second geographical area.

4. The method of claim 1, wherein each data point of the first set of data is defined temporally and spatially, the temporal definition including several temporal points throughout the first growing season, and the spatial definition including several spatial regions within the first geographic area.

5. The method of claim 4, wherein the first validating observation is limited to a single data point that is defined temporally and spatially, the spatial definition being the entire first geographic area, and the temporal definition being at or after harvest for the first growing season.

6. The method of claim 5, wherein developing the first primary model further comprises:
defining a second set of predictive variables, the second set of predictive variables comprising at least one predictive variable;
obtaining a second set of data for the second set of predictive variables, the second set of data comprising data for a plurality of data points associated with a second geographical area and a second growing season;
utilizing the second set of data with a third iteration of the primary model to obtain a third aggregate solution;
obtaining a second validating observation associated with the second geographic area and the second growing season;
calculating errors in the second iteration of the primary model by comparing the third aggregate solution with the second validating observation;
utilizing the calculated errors to develop a third correction model for identifying opportunities for making adjustments to the output of the primary model;
utilizing the third correction model and the second set of data with a fourth iteration of the primary model to obtain a fourth aggregate solution, the fourth aggregate solution being associated with the second geographical area and the second growing season; and
developing a fourth correction model.

7. The method of claim 6, wherein utilizing the primary model comprises utilizing the optimized iteration of the primary model to support enhanced agronomic decision-making in precision agriculture, thereby improving crop yield for the future harvest.

8. The method of claim 7, wherein utilizing the primary model comprises:
defining a current set of predictive variables, the current set of predictive variables comprising at least one of the first and second sets of predictive variables;
obtaining a current set of data for the current set of predictive variables, the current set of data comprising data for a plurality of data points associated with the selected geographical area and the current growing season;
utilizing the current set of data with the optimized iteration of the primary model to obtain a plurality of current aggregate solutions, each current aggregate solution being associated with an anticipated crop yield and a respective agronomic decision matrix; and
comparing the plurality of current aggregate solutions to determine an optimized crop yield.

9. The method of claim 8, wherein each data point of the current set of data is defined temporally and spatially, the temporal definition including several temporal points throughout the first growing season, and the spatial definition including several spatial regions within the first geographic area.

10. The method of claim 9, wherein the current set of predictive variables comprises satellite data.

11. A computer system comprising:
a computing environment including at least one computer-readable storage medium having program instructions stored therein and a computer processor operable to execute the program instructions to perform a multi-step iterative modeling process with a plurality of data processing modules, the plurality of data processing modules including:
a data ingest module, wherein the data ingest module is configured to receive input data relative to an agricultural process, and wherein the data ingest module is configured to request input data relative to the agricultural process;
a predictive variable identification module, the predictive variable identification module being configured to determine predictive variables that are relevant to the agricultural process; and
a primary simulation development module, the primary simulation module being configured to produce a plurality of simulated outcomes of the agricultural process, wherein at least one of the simulated outcomes is generated using at least some of the input data, and wherein at least one of the simulated outcomes is generated using at least one predictive variable.

12. The computer system of claim 11, the plurality of data processing modules further comprising an error calculation module, wherein the error calculation module is configured to determine errors in a at least one of the simulated outcomes of the primary simulation development module by identifying one or more validating observations, and wherein the error calculation module is configured to determine errors in the at least one simulated outcomes of the primary simulation development module by determining combinations among the predictive variables influencing the validating observations.

13. The computer system of claim 11, the plurality of data processing modules further comprising a correction module, the correction module being configured to reduce errors in the primary simulation development module, the correction module further being configured to identify adjustments to the primary simulation module, the correction module adjustments including variables that are analogous to the predictive variables determined by the predictive variable identification module, the correction module being configured to apply the correction module adjustments to at least one of the simulated outcomes of the primary simulation module to produce a modified simulated outcome of the agricultural process, and the correction module further comprising an artificial intelligence module.

14. The computer system of claim 11, wherein the input data includes a satellite image representing a crop yield for the agricultural process for an area during an agricultural period, and wherein the crop yield for the agricultural process represents an aggerate value of the yield during the agricultural period for the area.

15. The computer system of claim 11, wherein the input data includes satellite-based observations of a crop reflectance at different bands of the electromagnetic spectrum for the agricultural process for an area during an agricultural period, and wherein the satellite-based observations of the crop reflectance represents an aggerate value of the crop reflectance for the area during a time period, and wherein the an agricultural period is comprised of a plurality of time periods.

16. The computer system of claim 11, wherein the output data is a temporally disaggregated dataset, wherein the temporally disaggregated dataset incudes at least a portion of the input data, wherein the temporally disaggregated dataset includes at least one of the simulated outcomes generated using the at least one predictive variable, and wherein the temporally disaggregated dataset includes at least one modified simulated outcome of the agricultural process.

17. The computer system of claim 11, wherein the output data is a spatially disaggregated dataset, wherein the spatially disaggregated dataset includes at least a portion of the input data, wherein the spatially disaggregated dataset includes at least one of the simulated outcomes generated using the at least one predictive variable, and wherein and wherein the spatially disaggregated dataset includes at least one modified simulated outcome of the agricultural process.

18. The computer system of claim 11, wherein the output data represents a temporal disaggregation and a spatial disaggregation dataset specific to the agricultural process.

19. A computer implemented method of performing a multi-step iterative modeling process, the method comprising:
ingesting as input data, the input data being relative to an agricultural process, and wherein the input data relative to the agricultural process is associated with a growing season for an agricultural area;
modeling the input data in a plurality of data processing modules, wherein modeling input data in the plurality of data processing modules comprises:
determining a predictive variable dataset with a predictive variable identification module, the predictive variable identification module being configured to determine predictive variables that are relevant to the agricultural process;
developing a primary simulation module with a primary simulation development module, the primary simulation module being configured to produce a plurality of simulated outcomes of the agricultural process, and wherein at least one of the simulated outcomes is generated using at least one predictive variable;
developing an error generation module, wherein the error generation module is configured to determine errors in a at least one of the simulated outcomes of the primary simulation development module by identifying one or more validating observations, and wherein the error generation module is configured to determine errors in the at least one simulated outcomes of the primary simulation development module by determining combinations among the predictive variables influencing the validating observations; and
developing a correction module, the correction module being configured to reduce errors in the primary simulation development module.

20. The computer implemented method of claim 18, wherein the input data relative to the agricultural process includes a satellite image representing a crop yield for the agricultural process for the area during the growing season, wherein the crop yield for the agricultural process represents an aggerate value of the yield during the growing season for the area, and wherein the input data includes satellite-based observations of a crop reflectance at different bands of the electromagnetic spectrum for the agricultural process for the area during the growing season, and wherein the satellite-based observations of the crop reflectance represents an aggerate value of the crop reflectance for the area during a time period, and wherein the growing season is comprised of a plurality of time periods, the method further comprising generating output data, wherein the output data represents a temporal disaggregation and a spatial disaggregation dataset.
